(19) United States
(12) Patent Application Publication
(10) Pub. No.: US 2015/0069284 A1
(43) Pub. Date: Mar. 12, 2015

(54) NANOCOMPOSITE THERMOELECTRIC CONVERSION MATERIAL AND METHOD OF MANUFACTURING THE SAME

(71) Applicants: Toyota Jidosha Kabushiki Kaisha, Toyota-shi Aichi-ken (JP); Admatechs Company Limited, Miyoshi-shi Aichi (JP)

(72) Inventors: Junya Murai, Nissin-shi Aichi-ken (JP); Tomonari Kogure, Toyota-shi Aichi-ken (JP); Youichiro Kawai, Okazaki-shi Aichi-ken (JP); Yoshinori Okawauchi, Nagoya-shi Aichi-ken (JP)

(21) Appl. No.: 14/480,695

(22) Filed: Sep. 9, 2014

(30) Foreign Application Priority Data
Sep. 11, 2013 (JP) 2013-188477

(51) Int. Cl. H01L 35/18; H01L 35/12

(52) U.S. Cl. CPC H01L 35/18; H01L 35/12
USPC 252/62.3 T

(57) ABSTRACT

A nanocomposite thermoelectric conversion material includes: crystal grains of a matrix phase material; and a grain boundary phase that is formed in an interface between the crystal grains and includes an insulating material. In the interface between the crystal grains of the matrix phase material, an element that forms the matrix phase material and an element that forms the insulating material are bonded by a chemical bond.

### INCORPORATION BY REFERENCE

The disclosure of Japanese Patent Application No. 2013-188477 filed on Sep. 11, 2013 including the specification, drawings and abstract is incorporated herein by reference in its entirety.

### BACKGROUND OF THE INVENTION

1. Field of the Invention

The present invention relates to a nanocomposite thermoelectric conversion material and a method of manufacturing the same.

2. Description of Related Art

In recent years, in order to reduce an amount of carbon dioxide emissions from a viewpoint of a global warming problem, an interest in a technology for reducing a ratio of energy obtained from a fossil fuel is increasing. As one of such technologies, a thermoelectric conversion material that can directly convert untapped waste heat energy into electric energy and a thermoelectric conversion element that uses the thermoelectric conversion material can be cited. The thermoelectric conversion material is a material that converts heat directly into electric energy without utilizing a two-stage step like thermal power generation in which heat is once converted into kinetic energy and then converted into electric energy.

A conversion from heat to electric energy is performed by utilizing a temperature difference between both ends of a bulk body molded from a thermoelectric conversion material. A phenomenon in which a voltage is generated by the temperature difference was discovered by Seebeck and called a Seebeck effect. Performance of the thermoelectric conversion material is represented by a performance index Z obtained from the following formula.

Z=α²σ/κ(=Pf/κ)

Here, α represents a Seebeck coefficient of the thermoelectric conversion material, σ represents conductivity of the thermoelectric conversion material, and κ represents thermal conductivity of the thermoelectric conversion material. A term of α²σ is collectively called an output factor Pf. Then, Z has a dimension of an inverse number of temperature, and ZT obtained by multiplying an absolute temperature T and the performance index Z becomes a dimensionless value. The ZT is called a dimensionless performance index and used as an index that represents performance of the thermoelectric conversion material. Therefore, in order to improve the performance of the thermoelectric conversion material, as obvious from the formula shown above, the thermal conductivity κ is required to be further lower.

Japanese Patent No. 4645575 describes a thermoelectric material that includes at least one kind of element selected from the group consisting of Bi and Sb and at least one kind of element selected from the group consisting of Te and Se as a thermoelectric material including a microparticulated matrix phase material (see FIG. 1A). Japanese Patent No. 4645575 describes that the BiTe-based thermoelectric material described above can be obtained in such a manner that after an alloy as a starting material is extruded under a specific condition, a thermoelectric material is formed into a thin film by quenching with a liquid, after powderizing it, followed by solidifying and molding. According to the Japanese Patent No. 4645575, the thermoelectric material described above can simultaneously realize a high performance index and high mechanical strength or mechanical characteristics. However, when the thermoelectric material is formed of only the matrix phase material, there is a risk that crystal grains a of the matrix phase material are made coarser due to a high temperature environment during a manufacturing process or in the middle of use, and a sufficient reduction effect of the thermal conductivity cannot be obtained thereby.

Japanese Patent Application Publication No. 2003-37302 (JP 2003-37302 A) discloses a method of manufacturing a thermoelectric material, in which a quenched thin ribbon that includes an element that forms a matrix phase material is used. According to JP 2003-37302 A, it is described that when a microparticulated quenched thin ribbon is heat treated or solidified and molded, the thermal conductivity can be reduced and so on. However, it is considered that due to heat in the manufacturing process, a particle size is coarsened. A particle size of crystal grains of the matrix phase material of the actually obtained thermoelectric material is in a submicron level and it is considered that the reduction effect of the thermal conductivity due to microparticulation of the matrix phase material is insufficient. Further, it is considered that due to coarsening of the crystal grains of the matrix phase material due to usage for a long term, that is, deterioration, the thermal conductivity becomes not to be reduced.

As an example in which the thermoelectric material is formed into composite particles, Japanese Patent Application Publication No. 2012-104560 (JP 2012-104560 A) discloses a nanocomposite thermoelectric conversion material that includes insulating nanoparticles dispersed in a grain boundary. In Japanese Patent Application Publication No. 2000-261047 (JP 2000-261047 A), a thermoelectric conversion semiconductor material characterized by dispersing a ceramic powder as a dispersant in a main component of which a chemical composition is represented by CoSbₓ (2.7<x<3.4) is disclosed. Japanese Patent Application Publication No. 2010-114419 (JP 2010-114419 A) discloses a nanocomposite thermoelectric conversion material that includes nanoparticles b of a dispersant dispersed in a matrix phase a of the thermoelectric conversion material and has an interface roughness of 0.1 nm or more in an interface between the matrix phase a of the thermoelectric conversion material and a nanoparticle b of the dispersant (see FIG. 1A). According to JP 2010-114419 A, it is disclosed that due to the relevant structure, the thermal conductivity can be reduced. Japanese Patent Application Publication No. 2007-21670 (JP 2007-21670 A) discloses a thermoelectric conversion material that is formed into a core/shell structure having a plurality of core parts and a binding shell part that covers the core part. When the thermoelectric material is formed into composite particles like the thermoelectric conversion materials described in JP 2012-104560 A, JP 2000-261047 A, JP 2010-114419 A and JP 2007-21670 A, it is considered that a thermal scattering interface area becomes larger, and the thermal conductivity is reduced by a certain degree thereby. However, the thermoelectric conversion materials described in these documents are considered to be insufficient in a magnitude of the thermal scattering interface area. Further, also in the thermoelectric conversion materials described in these documents, in the same manner as Japanese Patent No. 4645575 and JP 2003-37302 A, it is considered that due to heat in the manufacturing step or long usage, the particle size is coarsened and the thermal conductivity becomes not to be reduced thereby.

Therefore, a thermoelectric conversion material that can maintain sufficiently reduced thermal conductivity even under various environments, in particular, under high temperature during manufacture and usage has been demanded.

### SUMMARY OF THE INVENTION

The present invention provides a nanocomposite thermoelectric conversion material that can make low thermal conductivity possible and a method of manufacturing the same.

The present inventors found that, in a nanocomposite thermoelectric conversion material that includes a matrix phase material and an insulating material, when a grain boundary phase including the insulating material in an interface between crystal grains of the matrix phase material is formed, even placed under a high temperature during a manufacturing process or under a service environment, crystal grains of the matrix phase material are reduced from being coarsened and the thermal conductivity is sufficiently reduced thereby.

A first aspect of the present invention relates to a nanocomposite thermoelectric conversion material that includes crystal grains of a matrix phase material and a grain boundary phase that is formed in an interface between the crystal grains and contains an insulting material. In the interface between the crystal grains of the matrix phase material, an element that forms the matrix phase material and an element that forms the insulating material are bonded by a chemical bond.

A particle size of the crystal grains of the matrix phase material may be 400 nm or less.

A thickness of the grain boundary phase including the insulating material may be 10 nm or less.

A second aspect of the present invention relates to a method of manufacturing a nanocomposite thermoelectric conversion material. The method of manufacturing includes: processing a solution that contains a precursor of an element that forms a matrix phase material and a precursor of an element that forms an insulating material with a reducing agent; obtaining composite particles that contains the element that forms the matrix phase material and the element that forms the insulating material by adding a basic compound to the processed solution described above; and heat treating the obtained composite particles.

The third aspect of the present invention relates to a thermoelectric conversion element that uses the nanocomposite thermoelectric conversion material described above.

According to the nanocomposite thermoelectric conversion material of the present invention, sufficiently reduced thermal conductivity can be achieved. In particular, the nanocomposite thermoelectric conversion material of the present invention is advantageous in a point that a degree of freedom in a back end step during manufacture and a service environment can be increased because sufficiently reduced thermal conductivity can be maintained even under a high temperature.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1A is a conceptual schematic diagram that shows a mode of a constituent phase of a conventional thermoelectric conversion material;

FIG. 1B is a conceptual schematic diagram that shows a mode of a constituent phase of a thermoelectric conversion material of the present invention;

FIG. 2 is a conceptual schematic diagram that shows variations of modes of the constituent phases of the conventional thermoelectric conversion material and the thermoelectric conversion material of the present invention under a high temperature;

FIG. 3A is a diagram that describes a reaction in a step (b) of an embodiment of a method of manufacturing of the present invention;

FIG. 3B is a diagram that describes a reaction in the step (b) of the embodiment of the method of manufacturing of the present invention;

FIG. 4 shows SEM (Scanning Electron Microscope) images of thermoelectric conversion materials before a sintering is applied after a heat treatment was applied in methods described in Example 1 and Comparative Example 1;

FIG. 5 shows TEM (Transmission Electron Microscope) images of the thermoelectric conversion materials (after sintering) of Example 1 and Comparative Example 1;

FIG. 6 is a graph that shows a relationship between a matrix crystal particle size and the thermal conductivity of thermoelectric conversion materials of Examples 1 to 10 and Comparative Example 1; and

FIG. 7 is a diagram that shows a chart of TOF-SIMS (Time-of-flight Secondary Ion Mass Spectrometer) of the thermoelectric conversion material of Example 1.

### DETAILED DESCRIPTION OF EMBODIMENTS

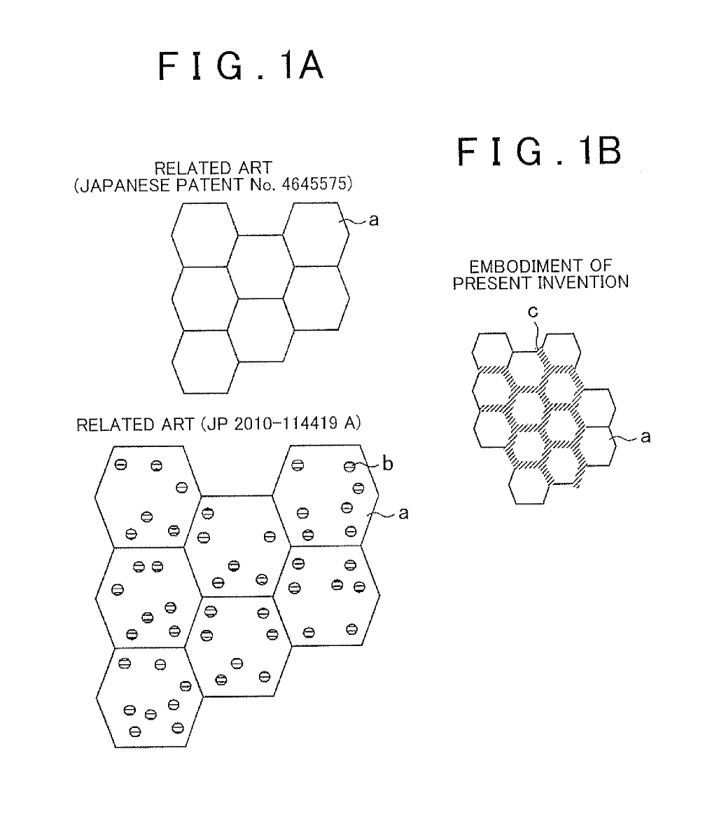

The nanocomposite thermoelectric conversion material of an embodiment of the present invention includes a matrix phase material and an insulating material, and, a grain boundary phase c including the insulating material is formed in an interface between crystal grains a of the matrix phase material (see FIG. 1B). In the nanocomposite thermoelectric conversion material of the embodiment of the present invention, since the grain boundary phase containing the insulating material is formed, heat is scattered in the interface, and the thermal conductivity is reduced thereby, and, even when exposed to a high temperature during a manufacturing step or a long term use, the crystal grains of the matrix phase material are suppressed from being coarsened due to a diffusion reaction of the matrix phase material. The nanocomposite thermoelectric conversion material of the embodiment of the present invention, even if it has an insulating grain boundary phase therein, can maintain the electric conductivity due to a tunnel effect.

Here, that “a grain boundary phase including the insulating material is formed in an interface between the crystal grains of the matrix phase material” can be confirmed by observing with a transmission electron microscope (TEM). For example, as shown in a TEM photograph (left) of FIG. 5, when another material is present so as to isolate between the crystal grains of the matrix phase material, it is said that the above-described grain boundary phase is formed.

As the matrix phase material in the nanocomposite thermoelectric conversion material, without particular restriction, for example, materials that contain at least two or more kinds of elements selected from Bi, Sb, Ag, Pb, Ge, Cu, Sri, As, Se, Te, Fe, Mn, Co, and Si, for example, crystals of BiTe system or a CoSb₃ compound that includes Co and Sb as main components and elements other than Co, Sb, for example, transition metal elements can be used. As the transition metal described above, Cr, Mn, Fe, Ru, Ni, Pt, Cu and the like can be used. As the matrix phase material described above, any one of a (Bi, Sb)₂(Te, Se)₃ system, a Bi₂Te₃ system, a (Bi, Sh)Te system, a Bi(Te, Se) system, a CoSb₃ system, a PbTe system, and a SiGe system can be preferably used.

In the nanocomposite thermoelectric conversion material, a particle size of the crystal grains of the matrix phase material is, from the viewpoint of sufficiently reducing the thermal conductivity, preferable to be 400 nm or less, more preferable to be 25 to 400 nm, particularly preferable to be 30 to 150 nm, and still more preferable to be 40 to 100 nm. A particle size of crystal grains of the matrix phase material shows a value after a sintering treatment. When crystal grains of the matrix crystal are microparticulated, the thermal conductivity is reduced, and a coefficient of thermal conductivity is drastically reduced. The particle size of the crystal grains of the matrix phase material can be measured by means of a method described in the following “3. Measurement of Particle Size of Crystals of Matrix Phase Material”. A particle size of the crystal grains of the matrix phase material of the nanocomposite thermoelectric conversion material of the embodiment of the present invention before the sintering treatment can be 0.2 to 1 times, preferably 0.5 to 1 times a value after the sintering.

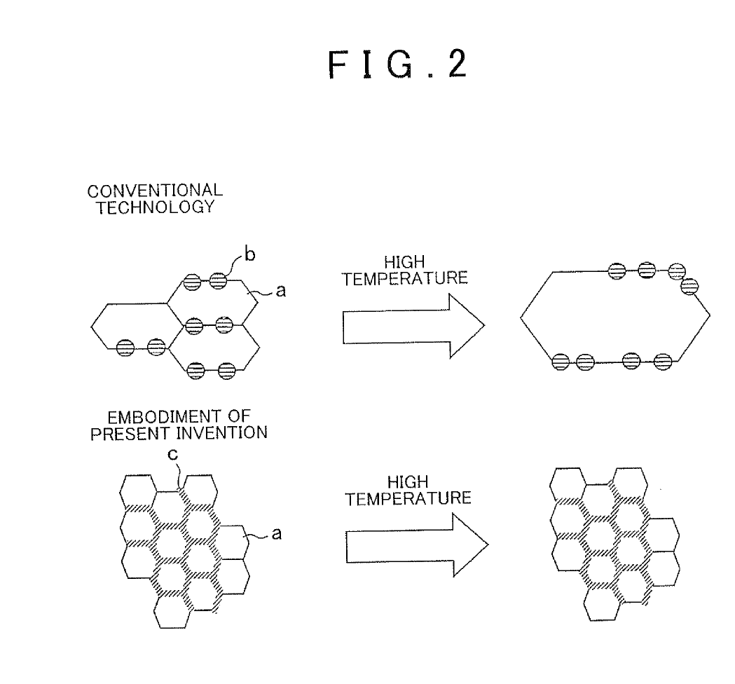

The insulating material in the nanocomposite thermoelectric conversion material is not particularly limited as long as it is a substance that does not advance the diffusion reaction with the matrix phase material. Specifically, inorganic insulating materials, for example, oxides of Si, Sb, Bi, Ti, Te, Se, Zr, Fe, Al, Cu, Ni, Mg, Mn, and Co and composite oxides including these, silicon carbide, aluminum nitride, silicon nitride and the like can be used. These insulating materials can be used singularly or in a combination of two or more kinds thereof. The insulating material is particularly preferable to be a substance that does not advance the diffusion reaction with the matrix phase material at a temperature of 0.5 to 1 times a melting temperature of the matrix phase material. Examples of such an insulating material include SiO₂, Sb₂O₃, Bi₂O₃, Bi₂TeO₅, BiSbO₄, TeO₃, SeO₂, TiO₂, Si₃N₄, SiC, ZrO₂ and Al₂TiO₅. When the insulating material that does not advance the diffusion reaction with the matrix phase material is formed as the grain boundary phase, the coarsening of the crystal grains of the matrix phase material can be suppressed from occurring even under high temperature during the manufacturing step thereafter or a long term use (see FIG. 2).

In the nanocomposite thermoelectric conversion material, a thickness of the grain boundary phase including the insulating material is, from the viewpoint of retaining the electric conductivity, preferably 10 nm or less, more preferably 0.5 to 10 nm, and particularly preferably 1 to 5 nm. The thickness of the grain boundary phase including the insulating material represents a value after the sintering treatment. The thickness of the grain boundary phase including the insulating material can be determined from a TEM image as described in the following “2. TEM Observation”.

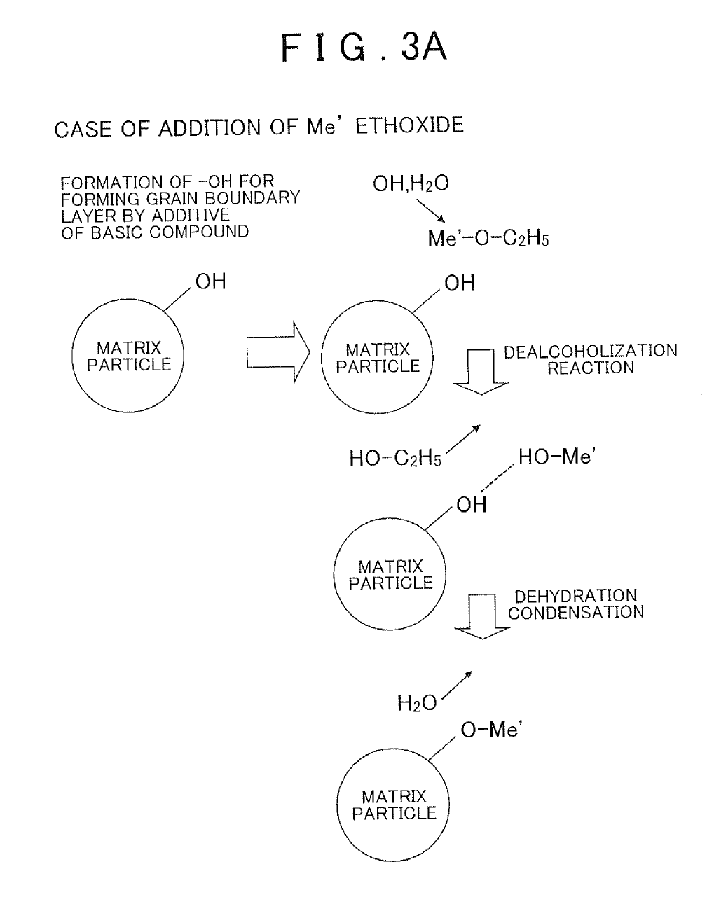

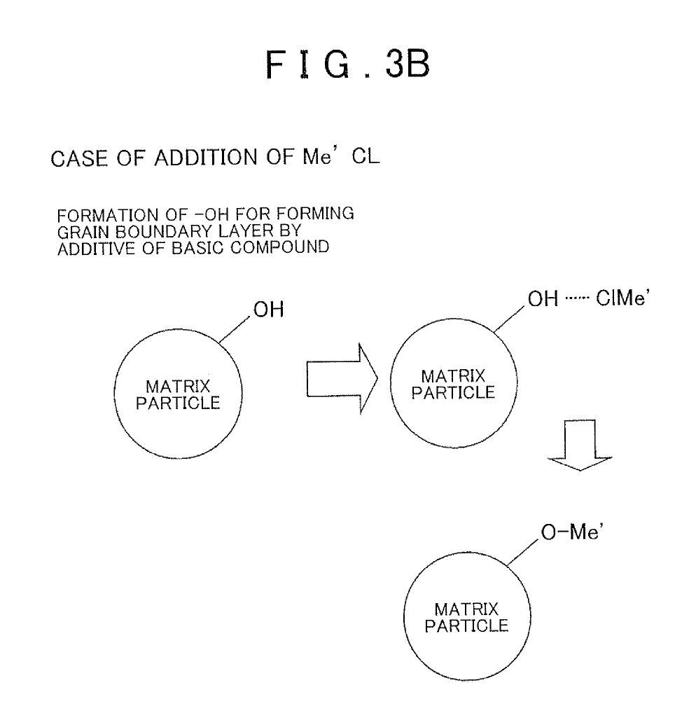

In the nanocomposite thermoelectric conversion material, in an interface between the crystal grains of the matrix phase material, an element that forms the matrix phase material and an element that forms the insulating material are bonded by a chemical bond (see FIG. 3A and FIG. 3B). Specifically, an element (Me) that forms the matrix phase material and an element (Me′) that forms the insulating material are bonded via any one of an oxygen atom (O), a carbon atom (C) and a nitrogen atom (N). This is confirmed because any one of “Me-O-Me”, “Me-C-Me” and “Me-N-Me′” can be detected when, for example, a time-of-flight secondary ion mass spectrometer (TOF-SIMS) is used. FIG. 3A and FIG. 3B show cases where the element (Me) that forms the matrix phase material and the element (Me′) that forms the insulating material are bonded via an oxygen atom (O).

A method of manufacturing suitable for manufacturing the nanocomposite thermoelectric conversion material of the embodiment of the present invention will be described below.

The method of manufacturing of the embodiment of the present invention includes the following steps of: (a) treating a solution that contains a precursor of an element that forms a matrix phase material and an element that forms an insulating material with a reducing agent; (b) obtaining composite particles that contain the element that forms the matrix phase material and the element that forms the insulating material by adding a basic compound to the treated solution; and (c) heat treating the obtained composite particles. The method of manufacturing of the embodiment of the present invention includes the step (b) of adding the basic compound and a grain boundary phase that includes the insulating material in an interface between the crystal grains of the matrix phase material can be formed thereby.

As the precursor of the element that forms the matrix phase material that is used in the step (a), salts of at least one or more kinds of elements selected from, for example, Bi, Sb, Ag, Ph, Ge, Cu, Sn, As, Se, Te, Fe, Mn, Co, and Si, preferably halides (for example chloride, fluoride and bromide), sulfates, nitrates of the elements described above and the like can be used, and, in particularly preferably, chlorides, sulfates, nitrates and the like can be used.

As the precursor of the element that forms the insulating material that is used in the step (a), as long as it forms hydroxide with a reducing agent and precipitates, without particular restriction, the element that forms the insulating material, specifically, halides (for example, chloride, fluoride and bromide), alkoxides and the like of Si, Sb, Bi, Ti, Te, Se, Zr, Fe, Al, Cu, Ni, Mg, Mn, and Co can be used. As the alkoxide, methoxide, ethoxide, propoxide, isopropoxide, butoxide, isobutoxide, tertiary butoxide, secondary butoxide, pentoxide, neopentoxide, tertiary pentoxide and the like can be used.

As the precursor of the element that forms a specific insulating material, tetraethoxysilane (TEOS: Si(OC₂H₅)₄), bismuth ethoxide (Bi(OC₂H₅)₃), titanium ethoxide (Ti(OC₂H₅)₄), titanium chloride (TiCl₄), iron chloride (FeCl₃), antimony ethoxide (Sb(OC₂H₅)₃), aluminum butoxide (Al(OC₄H₉)₃) can be used. No. 3 sodium silicate (Na₂O.3SiO₂aq) can also be used.

In the step (a), the solvent of the solution that contains the precursor of the element that forms the matrix phase material and the precursor of the element that forms the insulating material is not particularly restricted as long as it can uniformly disperse, in particular, dissolve the precursor of the element that forms the matrix phase material and the precursor of the element that forms the insulating material, and, for example, methanol, ethanol, 1-propanol, 2-propanol, dimethylacetamide, N-methyl pyrrolidone, propylene glycol monomethyl ether (PGM), acetone, ethylene glycol, methyl ethyl ketone, ethyl lactate and the like can be used.

The reducing agent used in the step (a) is not particularly restricted as long as it can reduce the precursor of the element that forms the matrix phase material. For example, tertiary phosphine, secondary phosphine and primary phosphine, hydrazine, hydrazine hydrate, a hydroxyphenyl compound, hydrogen, hydride, borane, aldehyde, reducing halide, a polyfunctional reductant, and the like can be used. Alkali boron hydride, for example, one kind or more of sodium boron hydride, potassium boron hydride, and lithium boron hydride can be used.

In the step (a), a mole ratio of the precursor of the element that forms the matrix phase material and the precursor of the clement that forms the insulating material is preferable to be 3:1 to 30:1, and particularly preferable to be 5:1 to 20:1.

The basic compound used in the step (b) is not particularly restricted as long as it is a substance that can form hydroxyl groups in an interface between the crystal grains of the matrix phase material under presence of water or alcohol. Specifically, a metal hydroxide, an inorganic anhydrous base, an inorganic salt of a weak acid, ammonia, amine and the like can be used. As the metal hydroxide, sodium hydroxide, barium hydroxide, strontium hydroxide and calcium hydroxide can be used. The inorganic anhydrous base is an inorganic compound that forms a hydroxide ion simultaneously with a reaction with water, for example, barium oxide and calcium oxide can be used. As the inorganic salt of the weak acid, carbonates such as potassium carbonate, sodium carbonate, and trisodium phosphate and phosphates can be used. As the amine, for example, methylamine, cyclohexylamine, benzylamine, aniline, o-toluidine, m-toluidine, p-toluidine, o-anisidine, m-anisidine, p-anisidine, 1-naphthylamine, 2-naphthylamine, 4-methoxy-2-methyl aniline, 4-tert-butyl aniline, N-methylaniline, N-ethylaniline, dibenzylamine, morpholine, pyrrolidone, piperidine and the like can be used. Further, the basic compound is preferable to be added in a state dissolved in water and alcohol, or the like, and is more preferable to be added in a state dissolved in water to make many hydroxide groups exist in the interface of the crystal grains of the matrix phase material.

The step (b) is preferable to be conducted under normal temperature, specifically, 15 to 35° C., from the viewpoint of making a large amount of the insulating material exist in the interface between the crystal grains of the matrix phase material.

In the step (b), the composite particles that contains the element that forms the generated matrix phase material and the element that forms the insulating material may be filtrated and cleansed with, for example, ethanol or a mixed solvent of a large amount of water and a small amount of ethanol (for example, water:ethanol=100:25 to 75 by a volume ratio).

In the step (c), the composite particles obtained in the step (b) are heat treated. For example, the composite particles obtained in the step (b) are heat treated in a hermetically sealed pressure vessel, for example, in a hermetically sealed autoclave, at a temperature of 150 to 450° C., preferably 180 to 400° C., and particularly preferably 200 to 350° C., and an alloy is formed thereby. The heat treatment is applied preferably for 4 to 100 hours and particularly preferably for 10 to 48 hours. Then, usually, under a non-oxidizing atmosphere, for example, under an inert atmosphere, the alloy is dried and a powdery nanocomposite thermoelectric conversion material can be obtained thereby.

When it is necessary to obtain a bulk body, the powdery nanocomposite thermoelectric conversion material described above is subjected to an SPS sintering (Spark Plasma Sintering) method at a temperature of 300 to 500° C. and a bulk body of the thermoelectric conversion material can be obtained. The SPS sintering can be applied with an SPS sintering machine that includes punches (an upper punch, a lower punch), electrodes (an upper electrode, a lower electrode), a die and a pressure device. Further, at the time of sintering, only a sintering chamber of the sintering device may be isolated from an external atmosphere and rendered into an inert sintering atmosphere or an entire system may be surrounded with a housing and rendered into an inert atmosphere.

A thermoelectric conversion element of the present invention can be obtained by assembling an N-type nanocomposite thermoelectric conversion material, a P-type nanocomposite thermoelectric conversion material, electrodes and an insulating substrate with the nanocomposite thermoelectric conversion material of the present invention according to a method known in itself.

Hereinafter, the present invention will be described with reference to examples. However, the present invention is not limited to the examples.

### EXAMPLE 1

<Preparation of Raw Material Solution>

A raw material solution was prepared by dissolving raw materials described below in 100 ml of ethanol.

Raw materials of matrix phase: bismuth chloride (BiCl₃): 0.4 g, tellurium chloride (TeCl₄): 2.56 g, antimony chloride (SbCl₃): 1.16 g

Insulating raw material: tetraethoxysilane (TEOS: Si(OC₂H₅)₄): 0.23 g.

<Reduction and Addition of Basic Compound>

A solution obtained by dissolving 2.4 g of NaBH₄ as a reducing agent in 100 ml of methanol was dropped in the raw material solution described above. In a slurry that contains nanoparticles precipitated by reduction, a solution in which 0.004 g of sodium hydroxide as the basic compound is dissolved in 10 ml of water was added, and mixed. The obtained slurry was filtrated and cleansed with 500 ml of water, and, further filtrated and cleansed with 300 ml of ethanol.

<Heat Treatment>

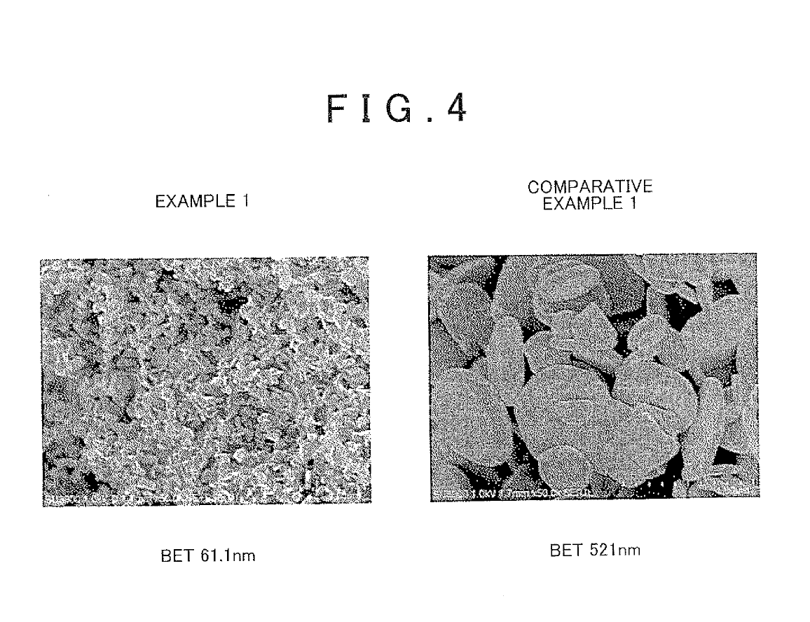

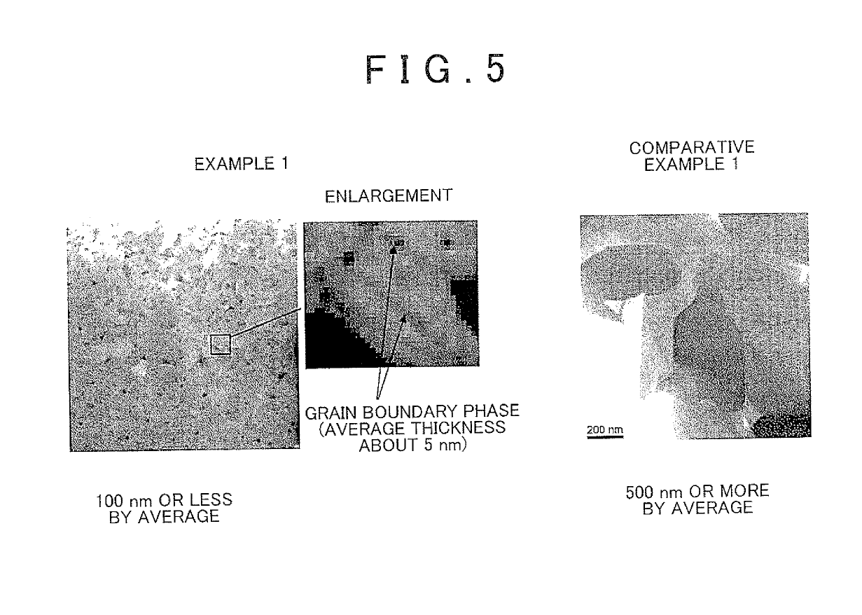

Thereafter, a residue was charged in a hermetically sealed autoclave, hydrothermally processed under the condition of 240° C.×48 hours, and the matrix was alloyed thereby. Then, the alloy was dried in a N₂ gas flow atmosphere, and powder was recovered. At that time, a powder of about 1.5 g was recovered (FIG. 4).

<Sintering>

The recovered powder was subjected to the spark plasma sintering (SPS) at 360° C., and a nanocomposite thermoelectric conversion material in which an oxide of silicon is formed in layer in an interface between crystal grains of a matrix made of (Bi, Sb)₂Te₃ was obtained thereby (FIG. 5).

### EXAMPLE 2

A nanocomposite thermoelectric convention material was prepared in the same manner as Example 1 except that 100 ml of ethanol was used as the solvent of the reducing agent. A nanocomposite thermoelectric conversion material in which an oxide of silicon is formed in layer in an interface between crystal grains of the matrix made of (Bi, Sb)₂Te₃ was obtained thereby.

### EXAMPLE 3

A nanocomposite thermoelectric convention material was prepared in the same manner as Example 1 except that 100 ml of ethanol was used as the solvent of the reducing agent and 0.28 g of triethoxy antimony (Sb(OC₂H₅)₃) was used as the insulating raw material. A nanocomposite thermoelectric conversion material in which an oxide of antimony is formed in layer in an interface between crystal grains of the matrix made of (Bi, Sb)₂Te₃ was obtained thereby.

### EXAMPLE 4

A nanocomposite thermoelectric convention material was prepared in the same manner as Example 1 except that 100 ml of 1-propanol was used as the solvent of the reducing agent and 0.1 ml of 28% ammonia water was used as an aqueous solution of the basic compound. A nanocomposite thermoelectric conversion material in which an oxide of silicon is formed in layer in an interface between crystal grains of the matrix made of (Bi, Sb)₂Te₃ was obtained thereby.

### EXAMPLE 5

A nanocomposite thermoelectric convention material was prepared in the same manner as Example 1 except that 3.5 g of hydrazine hydrate (NH₂NH₂.H₂O) was used as the reducing agent, 100 ml of 1-propanol was used as the solvent of the reducing agent and 0.13 g of No. 3 sodium silicate (Na₂O.3SiO₂aq) was used as the insulating raw material. A nanocomposite thermoelectric conversion material in which an oxide of silicon is formed in layer in an interface between crystal grains of the matrix made of (Bi, Sb)₂Te₃ was obtained thereby.

### EXAMPLE 6

A nanocomposite thermoelectric convention material was prepared in the same manner as Example 1 except that 100 ml of 1-propanol was used as the solvent of the reducing agent and 0.22 g of titanium chloride (TiCl₄) was used as the insulating raw material. A nanocomposite thermoelectric conversion material in which an oxide of titanium is formed in layer in an interface between crystal grains of the matrix made of (Bi, Sb)₂Te₃ was obtained thereby.

### EXAMPLE 7

A nanocomposite thermoelectric convention material was prepared in the same manner as Example 1 except that 100 ml of 2-propanol was used as the solvent of the reducing agent and 0.38 g of bismuth ethoxide (Bi(OC₂H₅)₃) was used as the insulating raw material. A nanocomposite thermoelectric conversion material in which an oxide of bismuth is formed in layer in an interface between crystal grains of the matrix made of (Bi, Sb)₂Te₃ was obtained thereby.

### EXAMPLE 8

A nanocomposite thermoelectric convention material was prepared in the same manner as Example 1 except that 3.5 g of hydrazine hydrate was used as the reducing agent, and 100 ml of 2-propanol was used as the solvent of the reducing agent. A nanocomposite thermoelectric conversion material in which an oxide of silicon is formed in layer in an interface between crystal grains of the matrix made of (Bi, Sb)2Te₃ was obtained thereby.

### EXAMPLE 9

A nanocomposite thermoelectric convention material was prepared in the same manner as Example 1 except that 100 ml of propylene glycol monomethyl ether (PGM) was used as the solvent of the reducing agent, 0.25 g of titanium ethoxide (Ti(OC₂H₅)₄) was used as the insulating raw material, and 0.1 ml of 28% ammonia water was used as an aqueous solution of the basic compound. A nanocomposite thermoelectric conversion material in which an oxide of titanium is formed in layer in an interface between crystal grains of the matrix made of (Bi, Sb)₂Te₃ was obtained thereby.

### EXAMPLE 10

A nanocomposite thermoelectric convention material was prepared in the same manner as Example 1 except that 100 ml of PGM was used as the solvent of the reducing agent. A nanocomposite thermoelectric conversion material in which an oxide of silicon is formed in layer in an interface between crystal grains of the matrix made of (Bi, Sb)₂Te₃ was obtained thereby.

### Comparative Example 1

<Preparation of Raw Material Solution>

A raw material solution was prepared by dissolving raw materials described below in 100 ml of ethanol.

Raw materials of matrix phase: bismuth chloride (BiCl₃): 0.4 g, tellurium chloride (TeCl₄): 2.56 g, antimony chloride (SbCl₃): 1.16 g

Insulating raw material: ethanol slurry of SiO₂ (ethanol: 10 ml, SiO₂: 0.15 g (19% by mass)).

<Addition of Reducing Agent>

A solution obtained by dissolving 2.4 g of NaBH₄ as a reducing agent in 100 ml of ethanol was dropped in the raw material solution described above. An ethanol slurry that contains nanoparticles precipitated by reduction was filtrated and cleansed with 500 ml of water, and, further filtrated and cleansed with 300 ml of ethanol.

<Heat Treatment>

Thereafter, the nanoparticles were charged in a hermetically sealed autoclave, hydrothermally processed under the condition of 240° C.×48 hours, and a matrix was alloyed thereby. Then, the alloy was dried in a N₂ gas flow atmosphere, and powder was recovered. At that time, the powder of about 1.5 g was recovered (FIG. 4).

<Sintering>

The recovered powder was subjected to the spark plasma sintering (SPS) at 360° C., a thermoelectric conversion material in which SiO₂ is dispersed as particles in a matrix made of a thermoelectric conversion material (Bi, Sb)₂Te₃ was obtained thereby (FIG. 5).

The nanocomposite thermoelectric conversion materials according to Examples 1 to 10 and Comparative Example 1 were evaluated according to methods shown below.

1. Preparation of TEM Samples

A sintered body having a diameter of 10 mm×1 to 2 mm was cut out into 1 to 2 mm×1 to 2 mm by Isomet. After that, mechanical polishing was performed until a thickness became 100 μm or less and a sample was prepared thereby. After that, the sample described above was bonded to a Cu mesh for use in TEM with an adhesive (product name: Araldite) and dried. Then, a dimple grinder (manufactured by GATAN) was used to apply mechanical grinding such that a part of the sample becomes a thickness of 20 μm or less. Thereafter, by means of Ar ion milling (manufactured by GATAN), the sample was made thinner until a thickness of the thinned part becomes 10 to 100 nm.

2. TEM Observation

A part of which thickness became 100 nm or less according to the step of sample preparation described above was observed with TEM. Conditions of TEM observation were as follows. Type of apparatus: TecnaiG2S-Twin TEM (manufactured by FEI Corporation), and acceleration voltage: 300 kV.

3. Measurement of Particle Size of Crystals of Matrix Phase Material

Particle sizes of about 500 to 700 particles of crystals were measured with TEM and an average value thereof was taken as a particle size of crystals of the matrix phase material.

4. Measurement of Lattice Thermal Conductivity

A steady state thermal conductivity evaluation method and a flash method (non-steady state method) (Flash method thermal conductivity meter manufactured by Netzsch) were used. The lattice thermal conductivity was calculated by subtracting carrier thermal conductivity (Ke 1) from entire thermal conductivity.

Ke 1=LσT

(L: Lorentz number, σ: electric conductivity (=1/specific resistance), T: absolute temperature).

Components used for manufacturing the thermoelectric conversion materials of Examples 1 to 10 and Comparative Example 1, and physical properties of the thermoelectric conversion materials of Examples 1 to 10 and Comparative Example 1 are shown in Table 1.

TABLE 1

| | | | | Particle | |
|---|---|---|---|---|---|
| | | | | Size of | |
| | | | | Crystals | |
| | | | | of Matrix | Lattice |
| | | Insulating | | (after | Thermal |
| | Reducing | Raw | Basic | sintering) | Conductivity |
| | agent/Solvent | Material | Additive | (nm) | (W/m/K) |
| Example 1 | NaBH₄/methanol | TEOS | NaOH | 131 | 0.35 |
| Example 2 | NaBH₄/ethanol | TEOS | NaOH | 232 | 0.41 |
| Example 3 | NaBH₄/ethanol | Sb | NaOH | 81 | 0.10 |
| | | ethoxide | | | |
| Example 4 | NaBH₄/1-propanol | TEOS | NH₃ | 26 | 0.06 |
| Example 5 | Hydrazine/1-propanol | No. 3 | NaOH | 55 | 0.10 |
| | | Sodium | | | |
| | | silicate | | | |
| Example 6 | NaBH₄/1-propanol | TiCl₄ | NaOH | 94 | 0.19 |
| Example 7 | NaBH₄/2-propanol | Bi | NaOH | 170 | 0.31 |
| | | ethoxide | | | |
| Example 8 | Hydrazine/2-propanol | TEOS | NaOH | 270 | 0.49 |
| Example 9 | NaBH₄/PGM | Ti | NH₃ | 110 | 0.22 |
| | | ethoxide | | | |
| Example 10 | NaBH₄/PGM | TEOS | NaOH | 74 | 0.12 |
| Comparative | NaBH₄/ethanol | SiO₂ | None | 600 | 0.72 |
| Example 1 | | | | | |

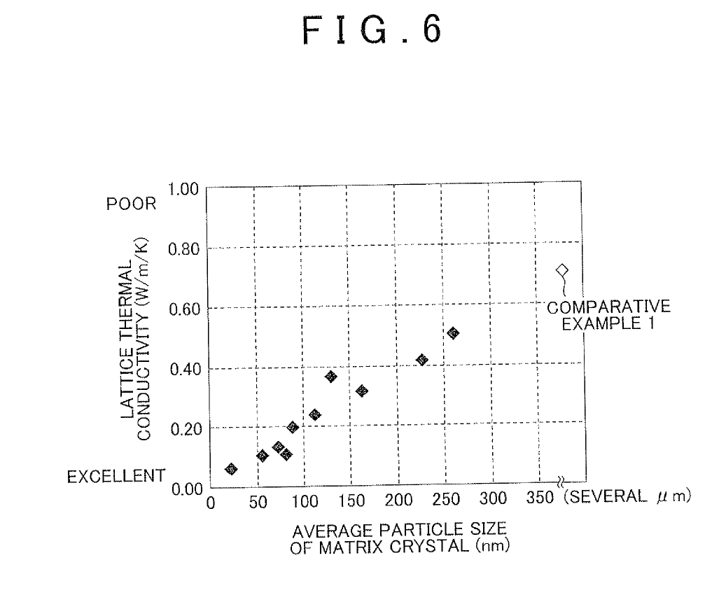

From Table 1, it is found that particle sizes of the matrix crystals (after sintering) in the thermoelectric conversion materials of Examples 1 to 10 are drastically smaller compared with that of the thermoelectric conversion material of Comparative Example 1. And from FIG. 6, it is found that the thermoelectric conversion materials of Examples 1 to 10 are sufficiently reduced in the thermal conductivity because the particle sizes of the matrix crystals are sufficiently reduced.

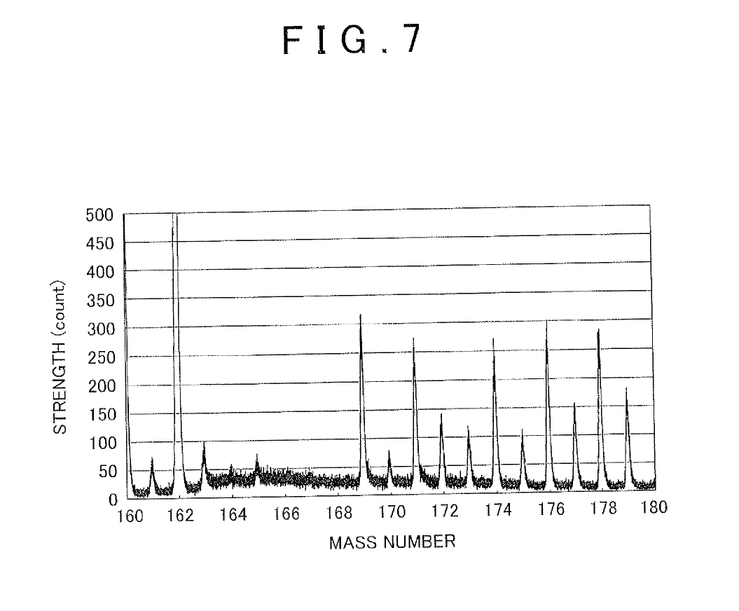

As shown in FIG. 7, according to measurements with TOF-SIMS of the thermoelectric conversion material of Example 1, peaks corresponding to mass numbers of the following secondary ions were observed.
Si—O—Te: 174
Si—O—Te: 172
Si—O—Sb: 165
   From this result, it is found that, in the thermoelectric conversion material of Example 1, an element that forms the matrix phase material and an element that forms the insulating material are bonded via an oxygen in an interface between the crystal grains of the matrix phase.

The thermoelectric conversion element that uses the nanocomposite thermoelectric conversion material of the present invention can be used for power generation that uses waste heat of a vehicle or geothermal heat, a power source for an artificial satellite and the like.

What is claimed is:

1. A nanocomposite thermoelectric conversion material comprising:
crystal grains of a matrix phase material; and
a grain boundary phase that is formed in an interface between the crystal grains and includes an insulating material,
wherein in the interface between the crystal grains of the matrix phase material, a first element that forms the matrix phase material and a second element that forms the insulating material are bonded by a chemical bond.

2. The nanocomposite thermoelectric conversion material according to claim 1, wherein
a particle size of the crystal grains of the matrix phase material is 400 nm or less.

3. The nanocomposite thermoelectric conversion material according to claim 1, wherein
a thickness of the grain boundary phase including the insulating material is 10 nm or less.

4. A method of manufacturing a nanocomposite thermoelectric conversion material comprising:
treating a solution containing a first precursor of a first element that forms a matrix phase material and a second precursor of a second element that forms an insulating material with a reducing agent;
obtaining a composite particle that contains the element that forms the matrix phase material and the element that forms the insulating material by adding a basic compound to the obtained solution; and
heat treating the obtained composite particle.

5. The method of manufacturing according to claim 4, wherein
a functional group is introduced in a matrix phase particle made of the matrix phase material by the basic compound, and the second element is bonded to the matrix phase particle by a condensation reaction of the second precursor and the functional group.

6. The method of manufacturing according to claim 5, wherein
the functional group is a hydroxyl group; and
the second precursor is a metal alkoxide or a halide.

7. A thermoelectric conversion element comprising:
the nanocomposite thermoelectric conversion material according to claim 1.
